(19) United States
(12) Patent Application Publication
(10) Pub. No.: US 2023/0386953 A1
(43) Pub. Date: Nov. 30, 2023

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Takashi TSUBAKIDANI, Tokyo (JP); Chihiro TADOKORO, Tokyo (JP)

(73) Assignee: Mitsubishi Electric Corporation, Tokyo (JP)

(21) Appl. No.: 18/177,373

(22) Filed: Mar. 2, 2023

(30) Foreign Application Priority Data
May 25, 2022 (JP) 2022-084896

(51) Int. Cl. H01L 23/31; H01L 23/29; H01L 21/306

(52) U.S. Cl. CPC H01L 23/3178; H01L 23/293; H01L 21/306

(57) ABSTRACT

A semiconductor device includes a semiconductor substrate in which an effective region through which a current flows and a termination region formed so as to surround an outer peripheral side of the effective region are defined, an oxide film provided in contact with an upper surface of the termination region so as to cover the upper surface, an organic insulating film containing an insulating material and provided so as to cover a portion of the oxide film excluding the peripheral portion, and at least one of a groove concave downward and a ridge protruding upward in the portion of the oxide film covered with the organic insulating film, in which the groove has a portion in which a width thereof decreases upward, and the ridge has a portion in which the width thereof increases upward.

### BACKGROUND OF THE INVENTION

### Field of the Invention

The present disclosure relates to a semiconductor device and a method of manufacturing the semiconductor device.

### Description of the Background Art

In a semiconductor device, an oxide film is provided on the upper surface of a semiconductor substrate, and polyimide is provided thereon. However, the adhesion between the oxide film and the polyimide is weak; therefore, if the device is continuously exposed to high humidity, moisture spreads from the interface between polyimide and the oxide film in the termination region over time. There has been a problem causing the electric field concentration between the outermost guard ring and the channel stopper.

In response to this, a semiconductor device has been proposed in which a groove is provided on the upper surface of the semiconductor substrate in the termination region to improve the moisture resistance without increasing the length of the termination region (for example, see International Publication No. 2020/105097).

However, the technique described in International Publication No. 2020/105097 has had a problem in that, the groove provided in the termination region takes a rectangular shape, which weakens the adhesion in terms of peeling in the vertical direction; therefore, when thermal stress is applied to the chip as in a power cycle, peeling occurs in the vertical direction.

### SUMMARY

An object of the present disclosure is to provide a technique that improves power cycle tolerance while improving the moisture resistance in a semiconductor device.

A semiconductor device according to the present disclosure includes a semiconductor substrate, an oxide film, a surface protective film, and at least one of concave portion and convex portion. The semiconductor substrate has a first main surface and a second main surface, a surface opposite to the first main surface, in which an effective region through which a current flows and a termination region formed so as to surround the outer peripheral side of the effective region are defined. The oxide film is provided in contact with the first main surface of the termination region covering the first main surface. The surface protective film contains an insulating material and provided so as to cover a portion of the oxide film excluding the peripheral portion. The concave portion is concave downward at a portion that is covered by the surface protective film. The convex portion protrudes upward at a portion that is covered by the surface protective film. The concave portion has a portion in which the width thereof decreases upward. The convex portion has a portion in which the width thereof increases upward.

The adhesion between the surface protective film and the semiconductor substrate improves, and the creeping distance from the outer peripheral end of the surface protective film to the inner peripheral side, for example, a guard ring is increased, so that the moisture resistance of the semiconductor device is improved. Further, the anchor effect produced by the concave portion or the convex portion improves the adhesion in the vertical direction of the semiconductor device, improving the power cycle tolerance of the semiconductor device.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a top view of a semiconductor device according to a first embodiment;

FIG. 2 is a cross-sectional view taken along the line A-A of FIG. 1;

FIG. 3 is a partial top view illustrating an example of a region corresponding to FIG. 2;

FIG. 4 is a partial top view illustrating another example of a region corresponding to FIG. 2;

FIG. 5 is a cross-sectional view corresponding to FIG. 2 of the second embodiment;

FIG. 6 is a cross-sectional view corresponding to FIG. 2 of the third embodiment;

FIGS. 7A to 7C are cross-sectional views illustrating a method of forming ridges in the third embodiment; and

FIG. 8 is a cross-sectional view corresponding to FIG. 2 of a fourth embodiment.

### DESCRIPTION OF THE PREFERRED EMBODIMENTS

### First Embodiment

### Configuration of Semiconductor Device

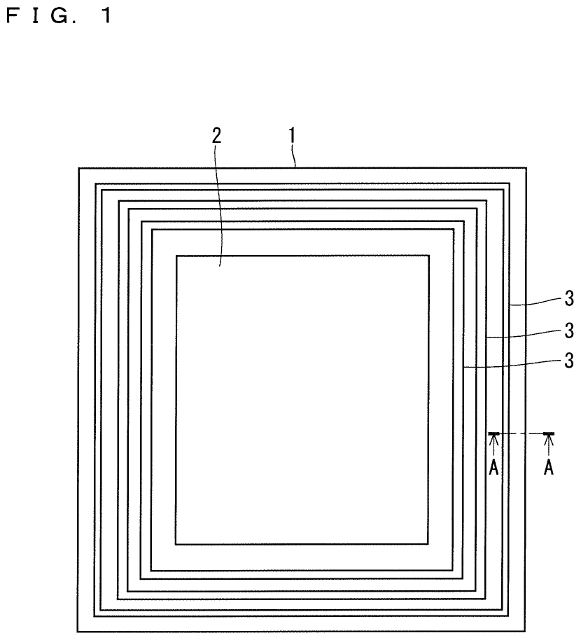

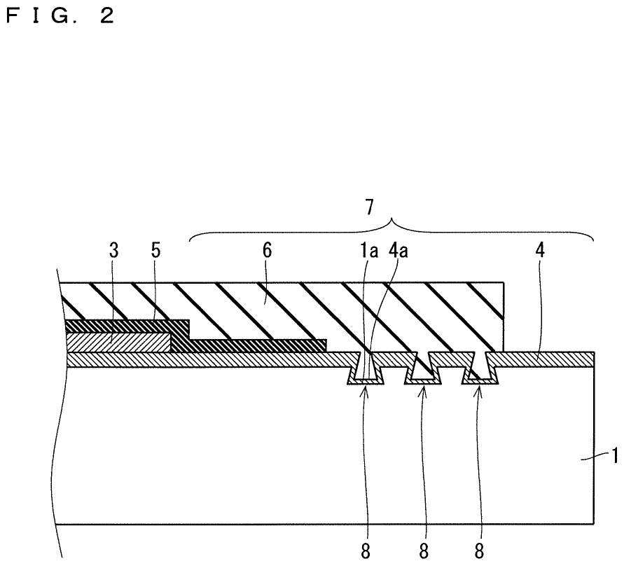

A first embodiment will be described below with reference to the drawings. FIG. 1 is a top view of a semiconductor device according to the first embodiment. FIG. 2 is a cross-sectional view taken along the line A-A of FIG. 1.

As illustrated in FIGS. 1 and 2, the semiconductor device includes a semiconductor substrate 1 defining an effective region 2 and a termination region 7, an oxide film 4, an insulating protective film 5, an organic insulating film 6 as a surface protective film, and grooves 8 as a concave portion concave downward.

As illustrated in FIG. 1, the effective region 2 through which current flows is defined in the central portion of a semiconductor substrate 1. The effective region 2 is provided with a transistor or diode (not illustrated). The semiconductor substrate 1 has an upper surface as a first main surface and a lower surface as a second main surface, a surface opposite to the first main surface. A plurality of (for example, three) guard rings 3 are provided on the upper surface of the semiconductor substrate 1 so as to surround the effective region 2.

As illustrated in FIG. 2, the oxide film 4 is provided on the upper surface of the semiconductor substrate 1. Specifically, the oxide film 4 is provided so as to contact and cover the upper surface of the semiconductor substrate 1 in the termination region 7. The semiconductor substrate 1 is a silicon substrate, and the oxide film 4 is a silicon oxide film. The plurality of guard rings 3 are selectively provided on parts of the upper surface of the oxide film 4. The insulating protective film 5 is selectively provided on a part of the upper surface of the oxide film 4 so as to cover the guard rings 3.

A semiconductor substrate 1 in a wafer state is diced into a chip, and the diced portion corresponds to the outer peripheral end of the semiconductor substrate 1, that is, the terminal end of the chip. The organic insulating film 6 is selectively provided on a part of the upper surface of the oxide film 4 so as to cover the insulating protective film 5. Specifically, the organic insulating film 6 contains an insulating material and is provided so as to cover the portion of the oxide film 4 excluding the peripheral portion. The organic insulating film 6 is, for example, polyimide. The organic insulating film 6 is in direct contact with the oxide film 4 in the termination region 7 between the outermost guard ring 3 and the outer peripheral edge of the semiconductor substrate 1. The organic insulating film 6 is not provided up to the peripheral portion of the semiconductor substrate 1.

In the present embodiment, at least one groove 8 is provided on the upper surface of semiconductor substrate 1 in the termination region 7. In the present embodiment, a case where a plurality of grooves 8 are provided will be described. The organic insulating film 6 is embedded in the groove 8, and the groove 8 has a portion in which the width thereof decreases upward. The width of the groove 8 indicates the width in the horizontal direction in FIG. 2. The groove 8 has a first concave portion 1a provided on the upper surface of the semiconductor substrate 1 and having an internal space having a trapezoidal cross-sectional shape, and a second concave portion 4a provided on the front surface of the first concave portion 1a and having an internal space formed of the oxide film 4 and having a trapezoidal cross-sectional shape.

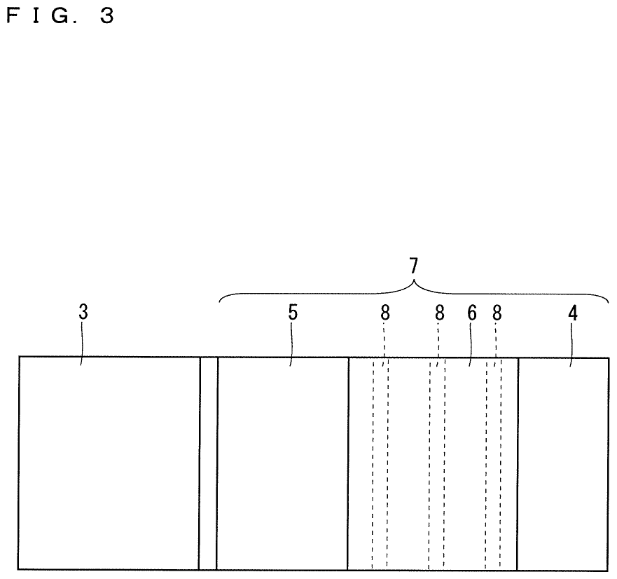

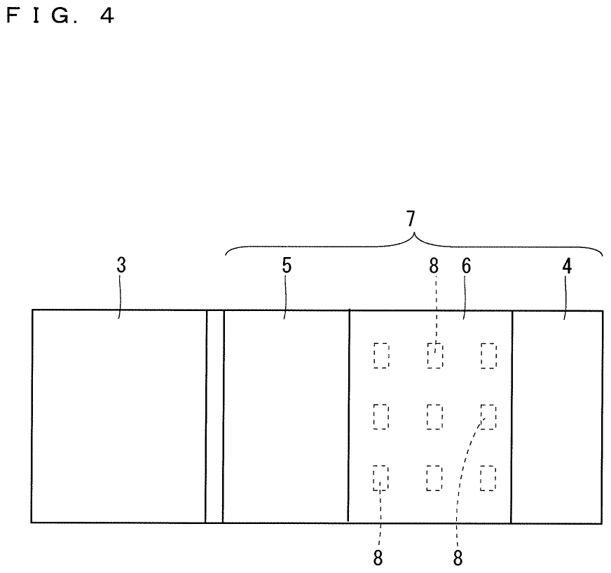

Next, the top view shape of the groove 8 will be described. FIG. 3 is a partial top view illustrating an example of a region corresponding to FIG. 2. FIG. 4 is a partial top view illustrating another example of a region corresponding to FIG. 2.

As illustrated in FIG. 3, the plurality of grooves 8 extend in parallel to the entire circumference of the top view contour of the organic insulating film 6. That is, the plurality of grooves 8 are provided so as to be parallel to the terminal end of the chip in top view, and are formed in a striped pattern.

Alternatively, as illustrated in FIG. 4, the plurality of grooves 8 may be formed not in a striped pattern but in a grid pattern in top view over the entire circumference of the organic insulating film 6.

### Method of Forming Groove

Next, a method of forming the groove 8 will be described. First, the oxide film 4 is formed on the upper surface of the semiconductor substrate 1. Next, trench etching is performed from the upper surface of the oxide film 4 to form the first concave portion 1a. By adjusting the etching conditions, the first concave portion 1a having a portion in which the width thereof decreases upward is formed. Alternatively, instead of trench etching, adjusting the doping amount of nitrogen in the drift layer also allows the formation of the first concave portion 1a having a portion in which the width thereof decreases upward.

Next, thermal oxidation is used to form the oxide film 4 on the front surface of the first concave portion 1a, thereby forming the second concave portion 4a. The second concave portion 4a is formed following the shape of the first concave portion 1a; therefore, the second concave portion 4a also has a portion in which the width thereof decreases upward.

### Effect

As described above, the semiconductor device according to the first embodiment includes the semiconductor substrate 1 having the upper surface and the lower surface, a surface opposite to the upper surface, in which the effective region 2 through which a current flows and the termination region 7 formed so as to surround the outer peripheral side of the effective region 2 are defined, the oxide film 4 provided in contact with the upper surface of termination region 7 so as to cover the upper surface, the organic insulating film 6 containing an insulating material and provided so as to cover a portion of the oxide film 4 excluding the peripheral portion, and grooves 8 as the concave portions concave downward in the portion of the oxide film 4 covered with the organic insulating film 6, and the grooves 8 have a portion in which the width thereof decreases upward. Further, the organic insulating film 6 contains polyimide.

Moisture enters from the outer peripheral edge of the organic insulating film 6 and spreads along the grooves 8; therefore, the creeping distance where the moisture reaches the outermost guard ring 3 is long. In addition, the grooves 8 are filled with the organic insulating film 6, which improves the adhesion between the organic insulating film 6 and the oxide film 4, so that the adhesion between the organic insulating film 6 and the semiconductor substrate 1 is improved. The spread of moisture from the outer peripheral edge of the organic insulating film 6 can be suppressed, improving the humidity resistance of the semiconductor device.

Further, the grooves 8 have a portion in which the width thereof decreases upward; therefore, the anchor effect produced by the grooves 8 improves the adhesion in the vertical direction of the semiconductor device, improving the power cycle tolerance of the semiconductor device.

Further, the termination region 7 is made shortened, which allows the chip size to be reduced, reducing the manufacturing cost of the semiconductor device.

Further the groove 8 has the first concave portion 1a provided on the upper surface of the semiconductor substrate 1 and having an internal space having a trapezoidal cross-sectional shape, and the second concave portion 4a provided on the front surface of the first concave portion 1a and having an internal space formed of the oxide film 4 and having a trapezoidal cross-sectional shape. Also, in a method of manufacturing the semiconductor device according to the first embodiment, the grooves 8 have the first concave portion 1a and the second concave portion 4a, and the method of manufacturing the semiconductor device includes Step (a) of forming the first concave portion 1a having an internal space having a trapezoidal cross-sectional shape provided on the upper surface of the semiconductor substrate 1, and Step (b) of forming the second concave portion 4a provided on the front surface of the first concave portion 1a and having an inner space made of the oxide film 4 and having a trapezoidal cross-sectional shape.

Therefore, the first concave portion 1a can be formed in the trench etching step, which is an existing step; therefore, formation of the groove 8 is ensured by simply adding Step (b) of forming the second concave portion 4a on the front surface of the first concave portion 1a to the existing step. This ensures realizing improvement of the moisture resistance and power cycle tolerance of the semiconductor device.

Further, the concave portion is a groove 8 parallelly extending with respect to the contour of the organic insulating film 6 in top view. Therefore, moisture that has entered from the outer peripheral edge of the organic insulating film 6 spreads toward the center of the semiconductor substrate 1; therefore, by providing the grooves 8 extending in a direction perpendicular to the direction of spreading of moisture, that is, in a direction parallelly extending with respect to the top view contour of the organic insulating film 6, the creepage distance from the outer peripheral edge of the organic insulating film 6 to the effective region 2 is made long.

In addition, the grooves 8 are formed in a grid pattern in top view, and the adhesion area between the organic insulating film 6 and the semiconductor substrate 1 in the termination region 7 increases, thereby improving the adhesion between the organic insulating film 6 and the semiconductor substrate 1 further.

### Second Embodiment

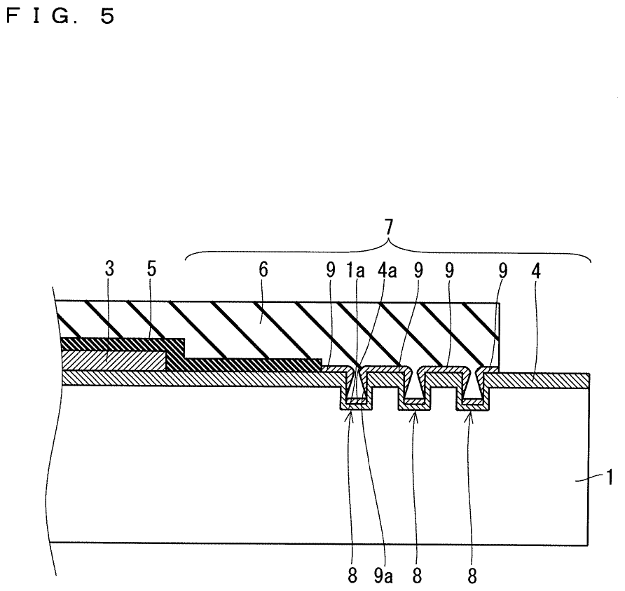

Next, a semiconductor device according to a second embodiment will be explained. FIG. 5 is a diagram of the second embodiment, corresponding to FIG. 2. In the second embodiment, the same components as those described in the first embodiment are denoted by the same reference numerals, and the description thereof is omitted.

### Configuration of Semiconductor Device

As illustrated in FIG. 5, in the second embodiment, the oxide film 4 inside the grooves 8 and around the grooves 8 is covered with an adhesion film 9 as a first adhesion film. The adhesion film 9 is a deposited oxide film. The grooves 8 have the first concave portion 1a, the second concave portion 4a, and a third concave portion 9a. The first concave portion 1a is provided on the upper surface of the semiconductor substrate 1, and the internal space thereof has a rectangular cross-sectional shape. The second concave portion 4a is provided on the front surface of the first concave portion 1a, and the internal space formed of the oxide film 4 has a rectangular cross-sectional shape. The third concave portion 9a is provided on the front surface of the second concave portion 4a, and the internal space formed of the adhesion film 9 has a trapezoidal cross-sectional shape. Specifically, the third concave portion 9a has a portion in which the width thereof decreases upward. The width of the third concave portion 9a indicates the width in the horizontal direction in FIG. 5.

### Method of Forming Groove

Next, a method of forming the groove 8 will be described. First, the oxide film 4 is formed on the upper surface of the semiconductor substrate 1. Next, trench etching is performed from the upper surface of the oxide film 4 to form the first concave portion 1a having an internal space having a rectangular cross-sectional shape. Alternatively, instead of trench etching, adjusting the doping amount of nitrogen in the drift layer also allows the formation of the first concave portion 1a.

Next, thermal oxidation is used to form the oxide film 4 on the front surface of the first concave portion 1a, thereby forming the second concave portion 4a having an internal space having a rectangular cross-sectional shape. Next, a deposited oxide film is deposited on the front surface of the oxide film 4 by a CVD method to form the adhesion film 9, thereby forming the third concave portion 9a having an internal space having a trapezoidal cross-sectional shape on the surface of the second concave portion 4a.

### Effect

As described above, in the semiconductor device according to the second embodiment, as in the case of the first embodiment, the groove 8 has a portion in which the width thereof decreases upward, improving power cycle tolerance while improving the moisture resistance.

Further the groove 8 has the first concave portion 1a provided on the upper surface of the semiconductor substrate 1 and having an internal space having a rectangular cross-sectional shape, the second concave portion 4a provided on the front surface of the first concave portion 1a and having an internal space formed of the oxide film 4 and having a rectangular cross-sectional shape, and the third concave portion 9a provided on the front surface of the second concave portion 4a and having an internal space formed of the adhesion film 9 having a trapezoidal cross-sectional shape. The adhesion film 9 includes a deposited oxide film. Also, in a method of manufacturing the semiconductor device according to the second embodiment, the grooves 8 have the first concave portion 1a, the second concave portion 4a, and the third concave portion 9a, and the method of manufacturing the semiconductor device includes Step (c) of forming the first concave portion 1a having an internal space having a rectangular cross-sectional shape provided on the upper surface of the semiconductor substrate 1, Step (d) of forming the second concave portion 4a provided on the front surface of the first concave portion 1a and having an inner space made of the oxide film 4 and having a rectangular cross-sectional shape, and Step (e) of forming the third concave portion 9a provided on the front surface of the second concave portion 4a and having an inner space formed of the adhesion film 9 having a trapezoidal cross-sectional shape.

The deposited oxide film is typically used in a semiconductor device as an interlayer film, and a deposited oxide film forming process is typically adopted in a manufacturing process of a semiconductor device. In the second embodiment, by forming a deposited oxide film after trench etching, the formation of the grooves 8 that can easily obtain an anchor effect by using existing processes is ensured.

### Third Embodiment

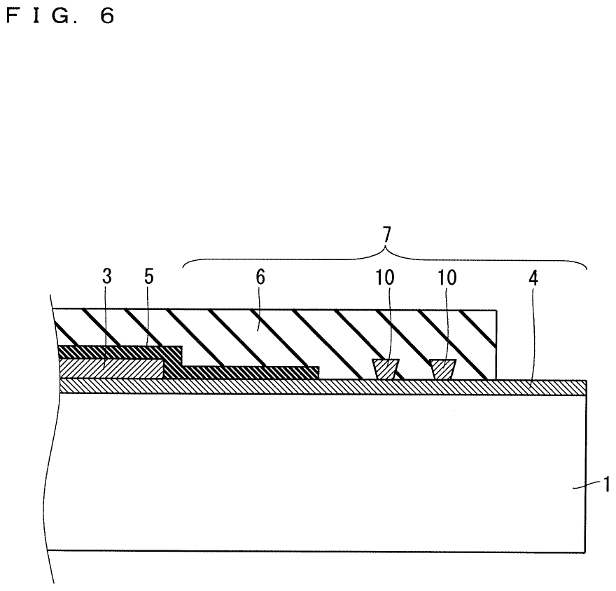

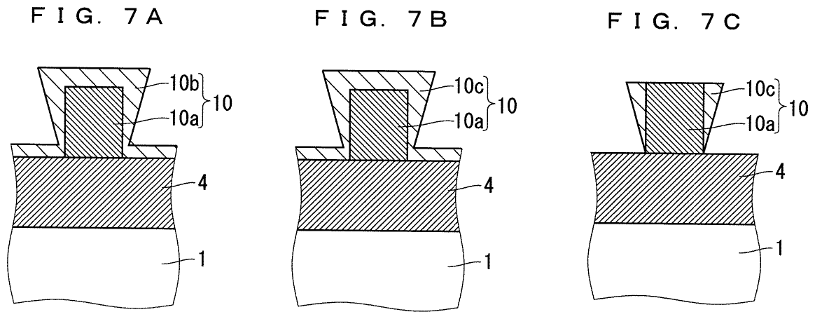

Next, a semiconductor device according to a third embodiment will be explained. FIG. 6 is a diagram of the third embodiment, corresponding to FIG. 2. FIGS. 7A to 7C are cross-sectional views illustrating a method of forming ridges 10 in the third embodiment. It should be noted that, in the third embodiment, the same components as those described in the first and second embodiments are denoted by the same reference numerals, and the description thereof is omitted.

### Configuration of Semiconductor Device

As illustrated in FIG. 6, in the third embodiment, at least one ridge 10 is provided between the oxide film 4 and the organic insulating film 6 in the terminal region 7 of the semiconductor substrate 1. In the present embodiment, a case where a plurality of ridges 10 (for example, two) are provided will be described. Here, the ridges 10 correspond to convex portions protruding upward. The ridges 10 are provided between the oxide film 4 and the organic insulating film 6 and are made of a second adhesion film including a deposited oxide film or a polysilicon film. The adhesion between the second adhesion film forming the ridges 10 and the organic insulating film 6 is higher than the adhesion between the organic insulating film 6 and the oxide film 4. The ridges 10 have a portion in which the width thereof increases upward. The width of the ridge 10 indicates the width in the horizontal direction in FIG. 6.

Further, although not illustrated, the plurality of ridges 10 extend in parallel to the entire circumference of the top view contour of the organic insulating film 6. That is, the plurality of ridges 10 are provided so as to be parallel to the terminal end of the chip in top view, and are formed in a striped pattern. Alternatively, the plurality of ridges 10 may be formed not in a striped pattern but in a grid pattern in top view over the entire circumference of the organic insulating film 6.

### Method of Forming Ridge

Next, a method of forming the ridge 10 will be described with reference to FIGS. 7A to 7C. On the oxide film 4 provided on the upper surface of semiconductor substrate 1, a primary pattern 10a of the second adhesion film to be the shape of ridge 10 is formed. The primary pattern 10a is made of a deposited oxide film. Next, the deposited oxide film 10b (see FIG. 7A) or a polysilicon film 10c (see FIG. 7B) is formed as a secondary pattern on a portion of the primary pattern 10a excluding the lower surface thereof. At this point, by adjusting film formation conditions, the deposited oxide film 10b or polysilicon film 10c formed on the side surfaces of the primary pattern is formed so that the upper portion is thicker than the lower portion. As a result, as illustrated in FIG. 7B, a ridge 10 having a cross-sectional shape whose width increases upward is formed.

Further, when the polysilicon film 10c is formed, as illustrated in FIG. 7C, the polysilicon film 10c formed on the upper surface of the ridge 10 and the upper surface of the oxide film 4 may be removed by reactive ion etching after the resist is applied.

### Effect

As described above, the semiconductor device according to the third embodiment includes, instead of the grooves 8 in the case of the first embodiment, in the portion of the oxide film 4 covered with the organic insulating film 6, the ridges 10 serving as convex portions protruding upward, and the ridges 10 have a portion in which the width thereof increases upward. Thereby, improving the power cycle tolerance while improving the moisture resistance.

The ridges 10 are provided between the oxide film 4 and the organic insulating film 6 and are made of a second adhesion film. Also, the second adhesion film includes a deposited oxide film or a polysilicon film. The adhesion between the second adhesion film forming the ridges 10 and the organic insulating film 6 is higher than the adhesion between the organic insulating film 6 and the oxide film 4; therefore, more improvement in the moisture resistance and power cycle tolerance than that in the case of the first embodiment is ensured.

Further, the convex portion is a ridge 10 parallelly extending with respect to the contour of the organic insulating film 6 in top view. Therefore, moisture that has entered from the outer peripheral edge of the organic insulating film 6 spreads toward the center of the semiconductor substrate 1; therefore, by providing the ridges 10 extending in a direction perpendicular to the direction of spreading of moisture, that is, in a direction parallelly extending with respect to the top view contour of the organic insulating film 6, the creepage distance from the outer peripheral edge of the organic insulating film 6 to the effective region 2 is made long.

In addition, the ridges 10 are formed in a grid pattern in top view, and the adhesion area between the organic insulating film 6 and the semiconductor substrate 1 in the termination region 7 increases, thereby improving the adhesion between the organic insulating film 6 and the semiconductor substrate 1 further.

### Fourth Embodiment

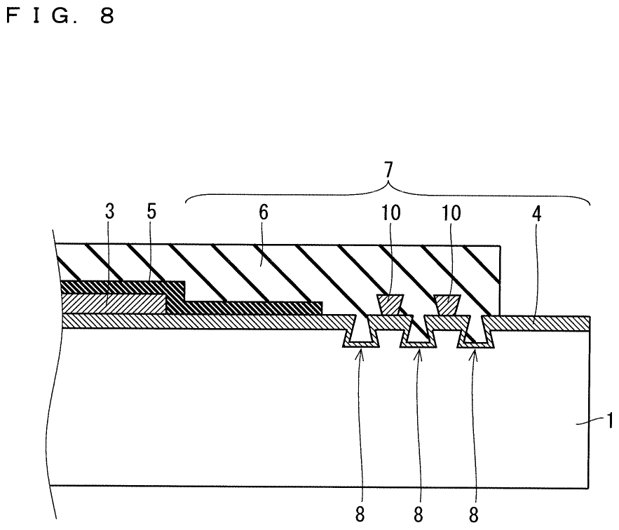

Next, a semiconductor device according to a fourth embodiment will be explained. FIG. 8 is a diagram of the fourth embodiment, corresponding to FIG. 2. It should be noted that, in the fourth embodiment, the description of the same components as those described in the first to third embodiments will be omitted here.

### Configuration of Semiconductor Device

As illustrated in FIG. 8, the fourth embodiment has a configuration in which the first and third embodiments are combined. At least one groove 8 is provided on the upper surface of semiconductor substrate 1 in the termination region 7. Also, at least one ridge 10 is provided between the oxide film 4 and the organic insulating film 6 in the terminal region 7 of the semiconductor substrate 1.

### Method of Forming Groove and Ridge

The grooves 8 are formed by the same method as in the first embodiment, and the ridges 10 are formed by the same method as in the third embodiment, so the description therefor is omitted here.

### Effect

As described above, the semiconductor device according to the fourth embodiment includes the grooves 8 as concave portions convex downward and the ridges 10 as convex portions protruding upward in the portion of the oxide film 4 covered with the organic insulating film 6, in which the grooves 8 have a portion in which the width thereof decreases upward and the ridges 10 have a portion in which the width thereof increases upward.

This makes the interface through which moisture spreads uneven, and the creepage distance for moisture to reach the outermost guard ring 3 is increased more than that in the case of the first embodiment without increasing the length of the termination region 7. Further, the adhesion area between the organic insulating film 6 and the oxide film 4 increases, and more improvement in the moisture resistance than that in the first embodiment is ensured.

### Modification Example of First to Fourth Embodiments

Although, the description of the semiconductor substrate 1 being made of silicon has been made in the first to fourth embodiments, the semiconductor substrate 1 is not limited to the one being made of silicon and may be the one made of a wide bandgap semiconductor having a larger bandgap than silicon. A wide bandgap semiconductor includes, for example, silicon carbide, gallium nitride-based materials, or diamond. Wide bandgap semiconductors are designed to have a high electric field strength at the interface; therefore, by adopting the configurations of the first to fourth embodiments for the semiconductor device including the semiconductor substrate 1 made of a wide bandgap semiconductor, the effect obtained from them becomes more remarkable and particularly effective.

The embodiments can be arbitrarily combined, appropriately modified or omitted.

Hereinafter, various aspects of the present disclosure will be collectively described as appendices.

### Appendix 1

A semiconductor device comprising;
a semiconductor substrate having a first main surface and a second main surface being a surface opposite to the first main surface, and in which an effective region through which a current flows and a termination region formed so as to surround an outer peripheral side of the effective region are defined;
an oxide film provided in contact with the first main surface of the termination region covering the first main surface;
a surface protective film containing an insulating material and provided so as to cover a portion of the oxide film excluding the peripheral portion; and
at least one of a concave portion concave downward and a convex portion protruding upward in the portion of the oxide film covered with the surface protective film, wherein
the concave portion has a portion in which a width thereof decreases upward, and
the convex portion has a portion in which the width thereof increases upward.

### Appendix 2

The semiconductor device according to Appendix 1, wherein
the concave portion has a first concave portion having an internal space having a trapezoidal cross-sectional shape provided on the first main surface of the semiconductor substrate, and a second concave portion provided on a front surface of the first concave portion and having an internal space formed of the oxide film having a trapezoidal cross-sectional shape.

### Appendix 3

The semiconductor device according to Appendix 1, wherein
the concave portion has a first concave portion having an internal space having a rectangular cross-sectional shape provided on the first main surface of the semiconductor substrate, a second concave portion provided on a front surface of the first concave portion and having an internal space formed of the oxide film having a rectangular cross-sectional shape, and a third concave portion provided on a front surface of the second concave portion and having an internal space formed of a first adhesion film having a trapezoidal cross-sectional shape.

### Appendix 4

The semiconductor device according to Appendix 3, wherein
the first adhesion film includes a deposited oxide film.

### Appendix 5

The semiconductor device according to Appendix 1, wherein
the convex portion is provided between the oxide film and the surface protective film and is made of a second adhesion film.

### Appendix 6

The semiconductor device according to Appendix 5, wherein
the second adhesion film includes a deposited oxide film or a polysilicon film.

### Appendix 7

The semiconductor device according to any one of Appendices 1 to 6, wherein
the concave portion is a groove parallelly extending with respect to a contour of the surface protective film in top view, and
the convex portion is a ridge parallelly extending with respect to the contour of the surface protective film in top view.

### Appendix 8

The semiconductor device according to any one of Appendices 1 to 6, wherein
the concave portion and the convex portion are formed in a grid pattern in top view.

### Appendix 9

The semiconductor device according to any one of Appendices 1 to 8, wherein
the surface protective film contains polyimide.

### Appendix 10

The semiconductor device according to any one of Appendices 1 to 9, wherein
the semiconductor substrate is made of a wide band gap semiconductor including silicon carbide, gallium nitride, or diamond.

### Appendix 11

A method of manufacturing the semiconductor device according to Appendix 1, wherein
the concave portion has a first concave portion and a second concave portion,
the method of manufacturing the semiconductor device comprising the steps of
(a) forming a first concave portion having an internal space having a trapezoidal cross-sectional shape provided on the first main surface of the semiconductor substrate; and
(b) forming a second concave portion provided on a front surface of the first concave portion and having an internal space formed of the oxide film having a trapezoidal cross-sectional shape.

### Appendix 12

A method of manufacturing the semiconductor device according to Appendix 1, wherein
the concave portion has a first concave portion, a second concave portion, and a third concave portion,
the method of manufacturing the semiconductor device comprising the steps of
(c) forming a first concave portion having an internal space having a rectangular cross-sectional shape provided on the first main surface of the semiconductor substrate;
(d) forming a second concave portion provided on a front surface of the first concave portion and having an internal space formed of the oxide film having a rectangular cross-sectional shape; and
(e) forming a third concave portion provided on a front surface of the second concave portion and having an internal space formed of a first adhesion film having a trapezoidal cross-sectional shape.

### Appendix 13

A method of manufacturing the semiconductor device according to Appendix 5, comprising the steps of:
(f) forming a primary pattern of the second adhesion film on the first main surface side of the semiconductor substrate; and
(g) forming the convex portion on the first main surface side of the semiconductor substrate by forming a secondary pattern of the second adhesion film on the primary pattern.

While the disclosure has been illustrated and described in detail, the foregoing description is in all aspects illustrative and not restrictive. It is therefore understood that numerous modifications and variations can be devised without departing from the scope of the invention.

What is claimed is:

1. A semiconductor device comprising;
a semiconductor substrate having a first main surface and a second main surface being a surface opposite to the first main surface, and in which an effective region through which a current flows and a termination region formed so as to surround an outer peripheral side of the effective region are defined;
an oxide film provided in contact with the first main surface of the termination region so as to cover the first main surface;
a surface protective film containing an insulating material and provided so as to cover a portion of the oxide film excluding the peripheral portion; and
at least one of a concave portion concave downward and a convex portion protruding upward in the portion of the oxide film covered with the surface protective film, wherein
the concave portion has a portion in which a width thereof decreases upward, and
the convex portion has a portion in which the width thereof increases upward.

2. The semiconductor device according to claim 1, wherein
the concave portion has a first concave portion having an internal space having a trapezoidal cross-sectional shape provided on the first main surface of the semiconductor substrate, and a second concave portion provided on a front surface of the first concave portion and having an internal space formed of the oxide film having a trapezoidal cross-sectional shape.

3. The semiconductor device according to claim 1, wherein
the concave portion has a first concave portion having an internal space having a rectangular cross-sectional shape provided on the first main surface of the semiconductor substrate, a second concave portion provided on a front surface of the first concave portion and having an internal space formed of the oxide film having a rectangular cross-sectional shape, and a third concave portion provided on a front surface of the second concave portion and having an internal space formed of a first adhesion film having a trapezoidal cross-sectional shape.

4. The semiconductor device according to claim 3, wherein
the first adhesion film includes a deposited oxide film.

5. The semiconductor device according to claim 1, wherein
the convex portion is provided between the oxide film and the surface protective film and is made of a second adhesion film.

6. The semiconductor device according to claim 5, wherein
the second adhesion film includes a deposited oxide film or a polysilicon film.

7. The semiconductor device according to claim 1, wherein
the concave portion is a groove parallelly extending with respect to a contour of the surface protective film in top view, and
the convex portion is a ridge parallelly extending with respect to the contour of the surface protective film in top view.

8. The semiconductor device according to claim 1, wherein
the concave portion and the convex portion are formed in a grid pattern in top view.

9. The semiconductor device according to claim 1, wherein
the surface protective film contains polyimide.

10. The semiconductor device according to claim 1, wherein
the semiconductor substrate is made of a wide band gap semiconductor including silicon carbide, gallium nitride, or diamond.

11. A method of manufacturing the semiconductor device according to claim 1, wherein
the concave portion has a first concave portion and a second concave portion, the method of manufacturing the semiconductor device comprising the steps of
(a) forming a first concave portion having an internal space having a trapezoidal cross-sectional shape provided on the first main surface of the semiconductor substrate; and
(b) forming a second concave portion provided on a front surface of the first concave portion and having an internal space formed of the oxide film having a trapezoidal cross-sectional shape.

12. A method of manufacturing the semiconductor device according to claim 1, wherein
the concave portion has a first concave portion, a second concave portion, and a third concave portion,
the method of manufacturing the semiconductor device comprising the steps of
(c) forming a first concave portion having an internal space having a rectangular cross-sectional shape provided on the first main surface of the semiconductor substrate;
(d) forming a second concave portion provided on a front surface of the first concave portion and having an internal space formed of the oxide film having a rectangular cross-sectional shape; and
(e) forming a third concave portion provided on a front surface of the second concave portion and having an internal space formed of a first adhesion film having a trapezoidal cross-sectional shape.

13. A method of manufacturing the semiconductor device according to claim 5, comprising the steps of:
(f) forming a primary pattern of the second adhesion film on the first main surface side of the semiconductor substrate; and
(g) forming the convex portion on the first main surface side of the semiconductor substrate by forming a secondary pattern of the second adhesion film on the primary pattern.
